(19) United States
(12) Patent Application Publication
(10) Pub. No.: US 2015/0093914 A1
(43) Pub. Date: Apr. 2, 2015

(54) METHODS FOR DEPOSITING AN ALUMINUM OXIDE LAYER OVER GERMANIUM SUSBTRATES IN THE FABRICATION OF INTEGRATED CIRCUITS

(71) Applicants: Intermolecular, San Jose, CA (US); GLOBALFOUNDRIES, Inc., Grand Cayman (KY)

(72) Inventors: Bin Yang, San Carlos, CA (US); Abhijit Pethe, San Jose, CA (US); Albert Lee, Cupertino, CA (US); Amol Joshi, Sunnyvale, CA (US); Ashish Bodke, San Jose, CA (US); Kevin Kashefi, San Ramon, CA (US); Salil Mujumdar, San Jose, CA (US)

(73) Assignees: Intermolecular, San Jose, CA (US); GLOBALFOUNDRIES, Inc., Grand Cayman (KY)

(21) Appl. No.: 14/044,514

(22) Filed: Oct. 2, 2013

(51) Int. Cl. H01L 21/02

(52) U.S. Cl. CPC H01L 21/02178
USPC 438/778

(57) ABSTRACT

Methods for fabricating integrated circuits are provided in various exemplary embodiments. In one embodiment, a method for fabricating an integrated circuit includes providing a germanium-based semiconductor substrate comprising a GeOₓ layer formed thereon and exposing the semiconductor substrate to first and second atomic layer deposition (ALD) processes. The first ALD process includes exposing the semiconductor substrate to a first gaseous precursor comprising aluminum and exposing the semiconductor substrate to a second gaseous precursor comprising a first oxygen-containing precursor. The second ALD process includes exposing the semiconductor substrate to a first gaseous precursor comprising aluminum and exposing the semiconductor substrate to a second gaseous precursor comprising a second oxygen-containing precursor.

### TECHNICAL FIELD

The present disclosure generally relates to methods for fabricating integrated circuits. More particularly, the presented disclosure relates to methods for depositing aluminum oxide layers over germanium substrates in the fabrication of integrated circuits.

### BACKGROUND

The majority of present day integrated circuits (ICs) are implemented by using a plurality of interconnected field effect transistors (FETs), also called metal oxide semiconductor field effect transistors (MOSFETs), or simply MOS transistors. An MOS transistor includes a gate electrode as a control electrode formed over a semiconductive substrate, and spaced apart source and drain electrodes within the substrate between which a current can flow. A control voltage applied to the gate electrode controls the flow of current through a channel in the semiconductive substrate between the source and drain electrodes.

The gain of an MOS transistor, usually defined by the transconductance (gₘ), is proportional to the mobility of the majority carrier in the transistor channel. The current carrying capability and hence the performance of an MOS transistor is proportional to the mobility of the majority carrier in the channel. With the continued scaling of modern MOSFETs, transistors fabricated using conventional bulk silicon substrates are approaching their fundamental limits with regard to carrier mobility. Thus, various other substrate materials have been investigated. One such material, germanium (Ge), exhibits carrier mobilities that are approximately two to four times higher than that of silicon.

In Ge-based MOSFETs, the “quality” of the MOS interface (i.e., the interface between the Ge substrate and the gate electrode) is one of several factors that allow for the realization of the above-noted improved carrier mobility in the channel. As conventionally used in the art, the “quality” of the MOS interface refers to the diffusional stability of the interface, as well as the adhesion of the interfacial layers. In order to promote interfacial stability and adhesion, an interfacial layer (IL) is conventionally provided between the Ge substrate and the first layer of the gate electrode, for example a high-k layer (i.e., having a dielectric constant greater than the dielectric constant of silicon dioxide). While various interfacial layers have been investigated, germanium oxide (GeOₓ) is the most widely used material due to its ease of growth on Ge (thermal oxidation in an oxidizing environment, for example) as well as its ability to adhere to both Ge and various high-k materials, which themselves are often metal oxides (for example, Al₂O₃ or HfO₂). In order to increase the carrier mobility performance of the transistor, it is desirable to provide an IL that is as thin as possible—that is, while the presence of the IL aides in stability and adhesion at the MOS interface, the IL detrimentally contributes to an increase in gate capacitance, which may harm transistor performance.

Atomic layer deposition (ALD) is commonly used to deposit the high-k dielectric layer over the thin GeOₓ interfacial layer. ALD requires several oxidation steps (“cycles”), where the deposited metal is oxidized to form the desired metal oxide, such as Al₂O₃. These oxidation steps, however, may undesirably result in the re-growth of additional GeOₓ, which as noted above may harm transistor performance. Attempts have been made in the prior art to reduce the level of oxidation during these cycles, or to reduce the total number of cycles (thereby creating a thinner dielectric layer), in an effort to prevent GeOₓ re-growth. Reduced levels of oxidation, however, detrimentally affect the nucleation (i.e., ordered bonding) of the deposited metal, which in turn may result in incomplete chemical bonding between the GeOₓ layer and the high-k layer. Incomplete chemical bonding between the layers may result in the formation of electron “traps.” As known in the art, these “traps” are localized areas within a semiconductor material that can attract or “trap” free electrical carriers. Traps may be caused by un-terminated or dangling electrochemical bonds at the interface of dissimilar materials such as GeOₓ and Al₂O₃. These unwanted energy traps may impair the electrical properties of material near the GeOₓ/Al₂O₃ interface and may reduce the performance of the transistor by increasing the density of energy states at the interface (Dᵢₜ). Furthermore, reducing the number of oxidation cycles, thereby creating a thinner dielectric layer, may result in gate current “leakage” (I_{g}), which reduces the stability of the transistor.

Accordingly, it is desirable to provide improved methods for fabricating integrated circuits using Ge-based semiconductor substrates. Additionally, it is desirable to provide such methods that include steps for the deposition of an aluminum oxide dielectric layer that do not substantially contribute to the re-growth of the germanium oxide interfacial layer, that do not substantially contribute to an increase in interface state density (Dᵢₜ), and that do not substantially contribute to increased gate current leakage (I_{g}). Furthermore, other desirable features and characteristics of the present disclosure will become apparent from the subsequent detailed description and the appended claims, taken in conjunction with the accompanying drawings and the foregoing technical field and background.

### BRIEF SUMMARY

Various exemplary methods for fabricating integrated circuits are provided herein. In one exemplary embodiment, a method for fabricating an integrated circuit includes providing a germanium-based semiconductor substrate comprising a GeOₓ layer formed thereon and exposing the semiconductor substrate to first and second atomic layer deposition (ALD) processes. The first ALD process includes exposing the semiconductor substrate to a first gaseous precursor comprising aluminum and exposing the semiconductor substrate to a second gaseous precursor comprising a first oxygen-containing precursor. The second ALD process includes exposing the semiconductor substrate to a first gaseous precursor comprising aluminum and exposing the semiconductor substrate to a second gaseous precursor comprising a second oxygen-containing precursor.

In another exemplary embodiment, a method for fabricating an integrated circuit includes providing a germanium-based semiconductor substrate comprising a GeOₓ layer formed thereon and exposing the semiconductor substrate to first and second atomic layer deposition (ALD) processes. The first ALD process includes exposing the semiconductor substrate to a first gaseous precursor comprising aluminum and exposing the semiconductor substrate to a second gaseous precursor comprising an oxygen-containing precursor at a first level. The second ALD process is performed subsequent to the first ALD process and includes exposing the semiconductor substrate to the first gaseous precursor comprising aluminum and exposing the semiconductor substrate to the second gaseous precursor comprising the oxygen-containing precursor at a second level that is less than the first level.

### BRIEF DESCRIPTION OF THE DRAWINGS

The various embodiments will hereinafter be described in conjunction with the following drawing figures, wherein like numerals denote like elements, and wherein:

FIG. 1 illustrates, in cross section, a germanium-based semiconductor substrate having an interfacial germanium oxide (GeOₓ) layer formed thereon;

FIG. 2 illustrates, in cross section, the deposition of an aluminum oxide layer by atomic layer deposition on the interfacial GeOₓ layer shown in FIG. 1;

FIG. 3 illustrates, in cross section, an integrated circuit structure and methods for fabricating an integrated circuit in accordance with various embodiments of the present disclosure; and

FIGS. 4-14 illustrate, in cross section, an integrated circuit structures and methods for fabricating integrated circuits in accordance with further embodiments of the present disclosure.

### DETAILED DESCRIPTION

The following detailed description is merely illustrative in nature and is not intended to limit the embodiments of the subject matter or the application and uses of such embodiments. Furthermore, there is no intention to be bound by any expressed or implied theory presented in the preceding technical field, background, brief summary or the following detailed description.

Embodiments of the present disclosure are directed to methods for depositing an aluminum oxide layer, which functions as a gate insulation layer for a gate electrode structure of an MOSFET, over germanium substrates using ALD in the fabrication of integrated circuits. In some embodiments of the present disclosure, GeOₓ re-growth is limited during ALD of the Al₂O₃ layer by using two (or more) different oxygen precursors in sequence during the various “cycles” of the ALD process. For example, during the first several deposition cycles a first oxygen precursor is employed, and during subsequent deposition cycles a second oxygen precursor is employed. The selection of various first and second oxygen precursors may be used in order to “tune” the qualities of the deposited aluminum oxide layer (for example, lower GeOₓ re-growth versus lower Dᵢₜ) to a specific application, as will be described in greater detail below. In other embodiments of the present disclosure, GeOₓ re-growth is limited during ALD of the Al₂O₃ layer by continuously decreasing the level of oxidation in the ALD process in each successive cycle. As such, the level of oxidation becomes a function of film thickness growth. For example, the initial deposition cycles are performed with a relatively high oxidation level in order to promote proper nucleation at the interface so that the bonding between the dissimilar interface materials (GeOₓ/Al₂O₃) is as strong as possible. Thereafter, subsequent cycles are performed with reduced oxidation levels as the Al₂O₃ layer builds on itself in order to minimize any GeOₓ re-growth. Methods in accordance with the present disclosure are easily integrated into existing integrated circuit fabrication process flows, and are suitable for use in both gate-first and gate-last process flows.

For the sake of brevity, conventional techniques related to semiconductor device fabrication may not be described in detail herein. Moreover, the various tasks and process steps described herein may be incorporated into a more comprehensive procedure or process having additional steps or functionality not described in detail herein. In particular, various steps in the manufacture of semiconductor based transistors are well known and so, in the interest of brevity, many conventional steps will only be mentioned briefly herein or will be omitted entirely without providing the well-known process details.

The techniques and technologies described herein may be utilized to fabricate MOS transistor devices, including NMOS transistor devices, PMOS transistor devices, and CMOS transistor devices. In particular, the process steps described here may be utilized in conjunction with any semiconductor device fabrication process that forms gate structures for transistors. Although the term “MOS device” properly refers to a device having a metal gate electrode and an oxide gate insulator, that term will be used throughout this disclosure to refer to any semiconductor device that includes a conductive gate electrode that is positioned over a high-k gate dielectric or other dielectric material, which in turn is positioned over a germanium-based semiconductor substrate.

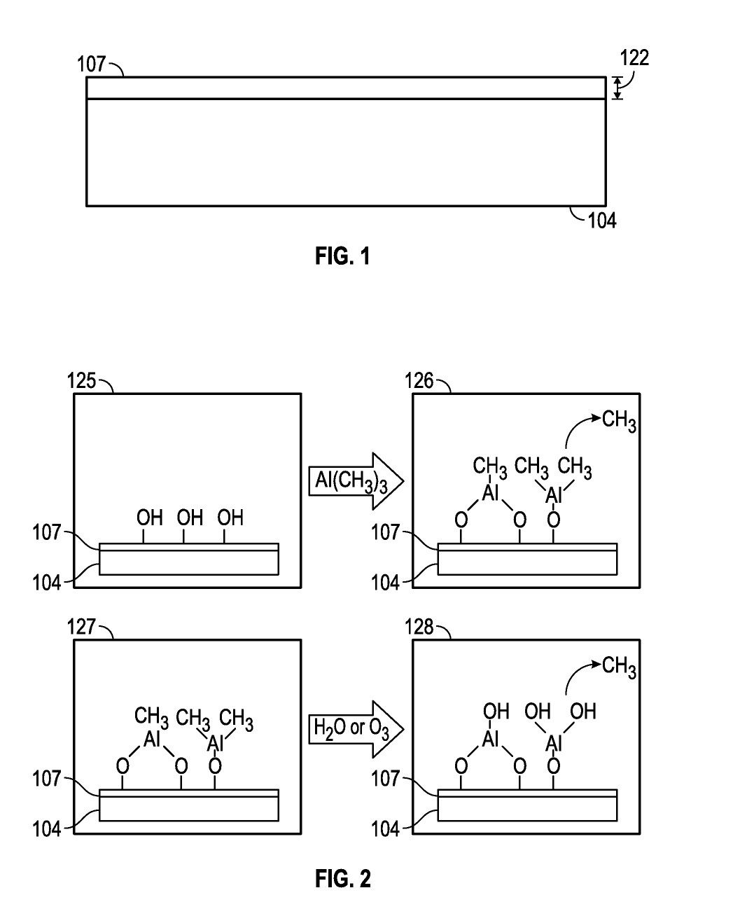

FIG. 1 illustrates, in cross section, a germanium-based semiconductor substrate 104 having a native oxide or thermally-grown oxide (GeOₓ) layer 107 formed thereon. In one example, semiconductor substrate 104 includes a crystalline Ge material configured in a (100) orientation. Oxide layer 107 is commonly present on substrate 104 as a result of exposure to an oxidizing ambient, such as air, subsequent to the formation of substrate 104. Alternatively, oxide layer 107 may be present on substrate 104 as a result of thermal treatment of the substrate 104 in an oxidizing environment. Oxide layer 107 has an initial thickness from about 0.1 nanometers (nm) to about 3 nm or greater in the case of a native oxide, or about 0.1 nm to about 10 nm or greater in the case of a thermally-grown oxide.

As noted above, while the presence of a GeOₓ interfacial layer is desirable to achieve a high quality MOS interface, if too thick the GeOₓ material undesirably increases the gate capacitance of a transistor formed thereof. An increased gate capacitance degrades the mobility of the carriers in the substrate 104. As such, it is desirable to minimize the thickness of the oxide layer 107 to a thickness 122 of about 5 nm or less, such as about 1 nm or less, for example about 5 angstroms (Å) or less. As such, prior to the deposition of the high-k dielectric layer, the substrate 104 is subjected to an etching or “cleaning” process in order to reduce the thickness of layer 107 to a desirable thickness 122 as noted above. This etching or cleaning process may be performed using any wet or dry etching chemistry known in the art that is selective to the GeOₓ material.

Subsequent to the initial substrate etch, a high-k dielectric material layer is formed over the interfacial GeOₓ layer 107 as a preliminary step in forming an MOSFET on the substrate 104. In one embodiment, the high-k dielectric material is aluminum oxide (Al₂O₃), which may be deposited using ALD. Referring now to FIG. 2, an exemplary process for the deposition of Al₂O₃ using ALD is illustrated. As known to those having ordinary skill in the art, ALD is a thin film deposition technique that is based on the sequential use of a gas phase chemical process. ALD reactions conventionally use two chemicals, typically called precursors. These precursors react with a surface one at a time in a sequential, self-limiting, manner. By exposing the precursors to the growth surface repeatedly, a thin film is deposited.

The growth of material layers by ALD includes repeating the following characteristic four steps: (1) Exposure of the first precursor in an energized state, typically an organometallic compound, such as aluminum. (2) Purge or evacuation of the reaction chamber to remove the non-reacted precursors and the gaseous reaction by-products. (3) Exposure of the second precursor in an energized state to activate the surface again for the reaction thereof with the first precursor. (4) Purge or evacuation of the reaction chamber. Each reaction cycle adds a given amount of material to the surface, referred to as the growth per cycle. To grow a material layer, reaction cycles are repeated as many times as required for the desired film thickness. One cycle may take about from about 0.5 seconds to a few seconds to complete, and may deposit between about 0.1 angstroms (Å) and about 3 Å of film thickness.

Referring now particularly to the ALD of Al₂O₃ as illustrated in FIG. 2, in step 125, the substrate 104 is provided into an ALD reaction chamber. The substrate 104 includes GeOₓ layer 107 formed thereon. As illustrated, the oxygen molecules of the GeOₓ layer 107 are hydrogen-terminated (or possibly hydroxyl-terminated), which results from the previously-described etching step. Thereafter, in step 126, the layer 107 is exposed to the first precursor, which in the case of Al₂O₃ is conventionally trimethylaluminum (TMA), having the chemical formula Al(CH₃)₃. The aluminum bonds with one or more of the oxygen atoms at the surface of the GeOₓ layer 107 to form a methyl-terminate aluminum layer, displacing at least one hydrogen radical (H⁺) and at least one methyl radical (CH₃⁻), which combine together in the gaseous phase to form a methane by-product. Thereafter, in step 127, the methane gas is purged from the reaction chamber. Further, in step 128, the methyl-terminated aluminum layer is exposed to the second precursor, which in the case of Al₂O₃ may be water (H₂O), ozone (O₃), hydrogen peroxide (H₂O₂), or any other oxygen-providing ALD precursor as are known in the art. One or more second precursor molecules bonds with an aluminum to form a hydroxyl-terminated aluminum layer (i.e., a hydrogen-terminated aluminum oxide layer), again displacing at least one hydrogen radical (H⁺) and at least one methyl radical (CH₃⁻), which combine together in the gaseous phase to form a methane by-product. Thereafter, the methane gas is purged from the reaction chamber. The steps 125-128 repeat in successive cycles as the Al₂O₃ layer is built-up to the desired thickness.

While each of the various second precursors noted above are suitable for use in forming an Al₂O₃ layer, the use of each of the second precursors has a different effect on the qualities of the dielectric layer formed and on the amount of GeOₓ re-growth that occurs underneath the dielectric layer. For example, performing ALD of Al₂O₃ using ozone as the second precursor provides good nucleation of the deposited aluminum oxide, thereby beneficially reducing the Dᵢₜ. However, using ozone as the second precursor also undesirably results in significant GeOₓ re-growth. In contrast, performing ALD of Al₂O₃ using water as the second precursor minimizes GeOₓ re-growth. However, using water as the second precursor undesirably increases the Dᵢₜ as it provides relatively weak nucleation of the deposited aluminum oxide.

Thus, in order to minimize Dᵢₜ while simultaneously minimizing GeOₓ re-growth, some embodiments of the present disclosure using two (or more) different oxygen pre-cursors in sequence during the various “cycles” of the ALD process. For example, during the first several deposition cycles a first oxygen precursor is employed, and during subsequent deposition cycles a second oxygen precursor is employed. The selection of various first and second oxygen precursors may be used in order to “tune” the qualities of the deposited aluminum oxide layer (for example, lower GeOₓ re-growth versus lower Dᵢₜ) to a specific application.

In one particular embodiment, the ALD of Al₂O₃ is performed wherein the initial few layers (for example, the first two or three layers) of Al₂O₃ are deposited using ozone as the second precursor, and the subsequent layers (until the desired layer thickness is formed) of Al₂O₃ are deposited using water as the second precursor. In this embodiment, using ozone for the first few layers provides good nucleation at the interface, where it is most effective at reducing Dᵢₜ due to the chemical bonding between the different interface materials. Thereafter, using water for the subsequent layers minimizes the re-growth of GeOₓ that occurs underneath the Al₂O₃, thereby allowing the Al₂O₃ to be formed to a sufficient thickness so as to minimize the I_{g}, such as from about 1 nm to about 8 nm, for example from about 1 nm to about 3 nm. In one embodiment, ALD is performed at a temperature of about 250° to about 350° C., such as about 300° C. Where ozone is the precursor, the layers are deposited by exposing the substrate to the ozone precursor for about 0.2 to about 2 seconds, for example about 1 second, and to the TMA precursor for about 1.5 to about 2.5 seconds, for example about 2 seconds. Where water is the precursor, the layers are deposited by exposing the substrate to the water precursor for about 4 to about 6 second, for example about 5 second, and to the TMA precursor for about 2 second to about 3 seconds, for example about 2.5 seconds.

In another particular embodiment, the ADL of Al₂O₃ is performed wherein the initial few layers (for example, the first two or three layers) of Al₂O₃ are deposited using water as the second precursor, and the subsequent layers (until the desired layer thickness is formed) of Al₂O₃ are deposited using ozone as the second precursor. In this embodiment, using water for the first few layers prevents significant re-growth of GeOₓ, as the first few layers are where the oxygen-containing second precursor comes in closest contact with the underlying GeOₓ layer. Thereafter, using ozone for the subsequent layers improves the bond ordering of the Al₂O₃ to prevent trapping and reduce Dᵢₜ. The process conditions for this embodiment are substantially as identified in the previous embodiment.

In some further embodiments of the present disclosure, GeOₓ re-growth is limited during ALD of the Al₂O₃ layer by continuously decreasing the level of oxidation in the ALD process in each successive cycle. In this manner, the level of oxidation becomes a function of film thickness growth. For example, the initial deposition cycles are performed with a relatively high oxidation level in order to promote proper nucleation at the interface so that the bonding between the dissimilar interface materials (GeOₓ/Al₂O₃) is as strong as possible. Thereafter, subsequent cycles are performed with reduced oxidation levels as the Al₂O₃ layer builds on itself in order to minimize any GeOₓ re-growth. Any of the above-mentioned second precursors are suitable for use in such methods.

In one particular embodiment, ozone is selected as the second precursor. For the first cycle, the exposure of the substrate 104 to the ozone (see step 128 of FIG. 2) is performed at about 250° to about 350° C., for example about 300° C. The substrate is exposed to the ozone for a time period of about 1.5 second to about 2.5 seconds, for example about 2 seconds. The substrate is exposed to the TMA for a time period of about 1.5 second to about 2.5 second, for example about 2 seconds. The second cycle is then performed in a similar manner. Thereafter, for the third cycle, the amount of ozone is reduced by about 5% or greater, such as by about 10% or greater, for example by about 20% or greater. Likewise, for subsequent cycles, the amount of ozone may be reduced by an additional about 5% or greater, such as an additional about 10% or greater, for example about 20% or greater. Of course, the reduction of oxidation level between successive cycles need not follow a linear relationship. The oxidation level may be reduced by different amounts between cycles, and the oxidation level may even remain constant between some cycles. For example, if the substrate is exposed to the ozone for a time period of about 2 seconds to about 20 seconds in one cycle, the exposure time may be reduced to a time period of about 0.05 seconds to about 18 seconds in a subsequent cycle. In one particular example, the substrate is exposed to the ozone for a time period of about 2 seconds in the first cycle, for about 2 seconds in the second cycles, for about 1.6 seconds in the third cycle, for about 1.2 seconds in the fourth cycle, for about 0.8 seconds in the fifth cycle, for about 0.4 seconds in the sixth cycle, and for about 0.2 seconds in the seventh and eighth cycles (of course, the minimum amount depends on ALD tool configuration). TMA exposure time remains constant in each cycle at about 1.5 second to about 2.5 second, for example about 2 seconds. Two, three, four, five, six, seven, eight, or more cycles may be employed in a given embodiment.

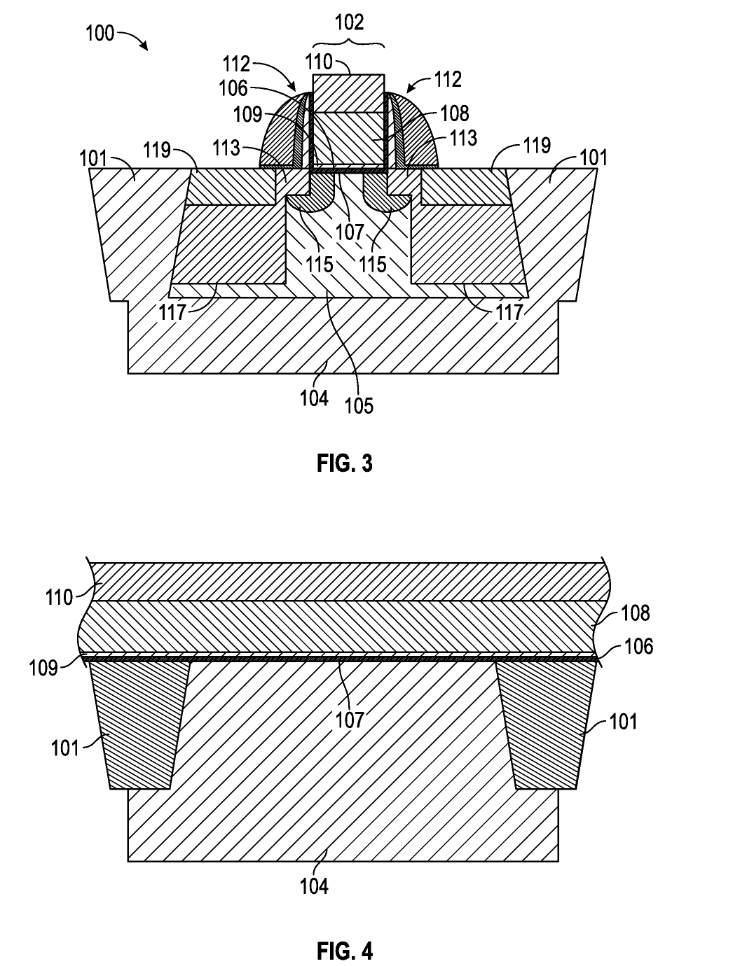

Reference is now made to FIG. 3, which illustrates the fabrication state of an integrated circuit device structure after the formation of a gate stack structure 102 overlying the Ge-based substrate 104, which is performed subsequent to the formation of the high-k dielectric layer (shown as layer 106 in FIG. 3) as described above. The integrated circuit is formed using well-known techniques and process steps (e.g., techniques and steps related to doping, photolithography and patterning, etching, material growth, material deposition, surface planarization, and the like) that will not be described in detail here.

As illustrated, one or more isolation regions 101 may be formed that extend into semiconductor material 104 to electrically isolate a plurality of transistors from one another. The isolation regions 101 are preferably formed by well-known shallow trench isolation (STI) techniques in which trenches are etched into semiconductor material 104, the trenches are filled with a dielectric material such as deposited silicon dioxide, and the excess silicon dioxide is removed by chemical mechanical planarization (CMP). STI regions 101 provide electrical isolation, as needed, between various devices of the integrated circuit that are to be formed. STI regions 101 are filled with a dielectric material such as an insulating oxide material.

In some embodiments, the gate stack structure 102 includes, without limitation: the gate insulation layer 106 overlying the IL (although the elements of the figures are not drawn in proportion relative to each other, because of the thinness of IL 107, IL 107 appears as a line in the figure), both of which are formed as described above; a metal gate electrode element 108 overlying the gate insulation layer 106; and one or more spacer structures 112 adjacent to vertical sidewalls of the gate electrode element 108. The gate stack structure 102 may also include a capping layer 110 (which may be formed from a nitride, a silicide, or other material) formed over the gate electrode element 108. Further, the gate stack structure 102 may optionally include a work function modifying material 109, such as lanthanum (La) or aluminum (Al), which may be disposed in between the gate insulation layer 106 and the metal gate electrode element 108.

As initially noted above, the metal gate stack structure 102 may be formed using either “gate first” or “gate last” process flows, as are well-known in the art. In one embodiment, the metal gate stack structure 102 is formed using a “gate first” metal gate process flow as will be described in greater detail below with continuing reference to FIG. 4. Formation of the metal gate stack 102, in a gate first process, begins with the formation of gate insulation layer 106 over IL 107, as described above. The overall thickness of the gate insulation layer 106 is, as noted above, from about 1 nm to about 3 nm. In an exemplary embodiment, the layer 106 is an ALD-deposited Al₂O₃ layer.

Continuing with the description of the exemplary gate first process flow, the work function modifying material 109 is optionally deposited subsequent to the formation of layer 106 and, as noted above, may include one or more of La and Al, for example, or other materials as are known in the art. Material 109 may be deposited using a suitable deposition technique such as atomic layer deposition (ALD), CVD, LPCVD, semi-atmospheric chemical vapor deposition (SACVD), or PECVD. The work function modifying material 109 may be deposited to a thickness sufficient to achieve the desired work function modification effect, such as from about 2 Å to about 2 nm.

Thereafter, the gate electrode element 108 may be formed by electroplating, CVD, ALD, or PVD. In some embodiments, the gate electrode element 108 is conformally deposited using CVD or ALD. The gate electrode element 108 may be formed to a thickness from about 5 nm to about 50 nm. The gate electrode element 108 may be a metal such titanium (Ti), titanium nitride (TiN), titanium-aluminum (TiAl), aluminum (Al), aluminum nitride (AlN), tantalum (Ta), tantalum nitride (TaN), tantalum carbide (TaC), tantalum carbonitride (TaCN), tantalum silicon nitride (TaSiN), tantalum silicide (TaSi), tungsten (W), and the like. In one embodiment, the gate electrode element 108 includes TiN. The capping layer 110 may thereafter be deposited using a material such as a polysilicon, a silicon nitride, or a silicide.

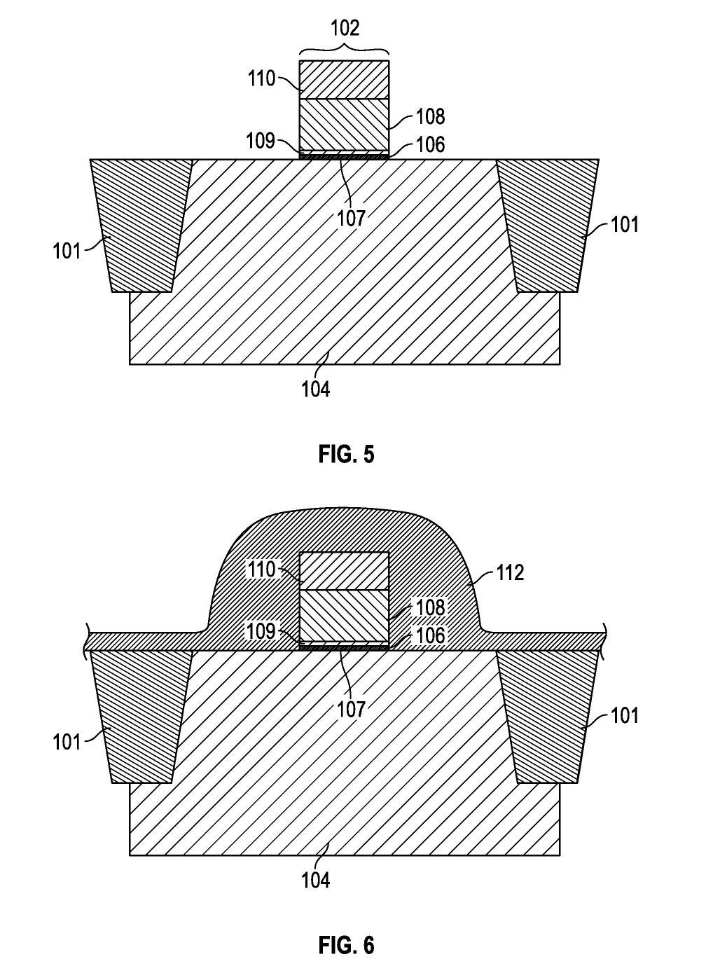

With reference now to FIG. 5, the gate stack structure 102 is formed using known photolithographic patterning and etching procedures. That is, a photoresist layer is deposited and then is exposed to an image pattern and treated with a developing solution to form pattern openings within the photoresist layer. With the openings thus formed, the deposited layer may be etched to form gate stack structure 102 by, for example, RIE using a suitable etching chemistry

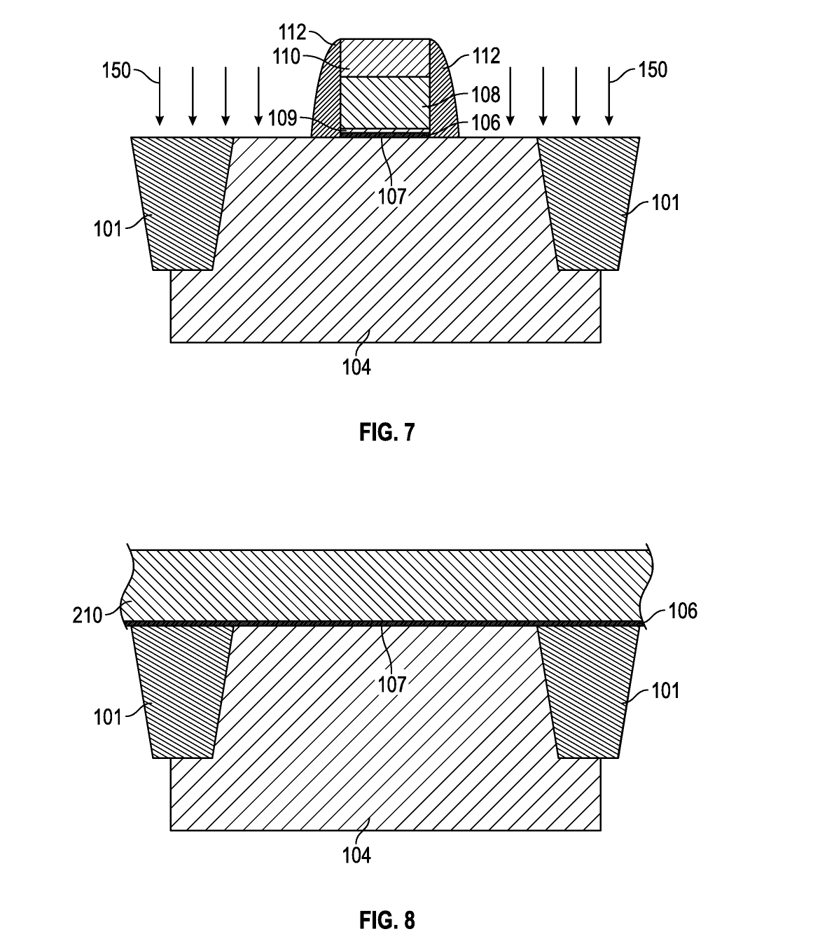

Turning to FIG. 6, the spacer structures 112 may thereafter be formed by conformally depositing one or more dielectric materials over the germanium substrate 104 and the metal gate stack 102, where the dielectric material is an appropriate insulator, such as silicon nitride. The dielectric spacer material(s) may be deposited in a known manner by, for example, atomic layer deposition (ALD), CVD, LPCVD, semi-atmospheric chemical vapor deposition (SACVD), or PECVD. The layer of dielectric spacer material is deposited to a thickness so that, after anisotropic etching, the spacer structures 112 formed from the layer have a thickness that is appropriate for the subsequent process steps described below. In some embodiments, the layer of dielectric spacer material is deposited to a thickness of about 5 nm to about 50 nm. The process continues, in accordance with an exemplary embodiment, with anisotropic etching of the layer(s) of dielectric spacer material(s) to form the spacer structures 112, as illustrated in FIG. 7. The layer(s) of dielectric spacer material(s) may be etched by, for example, RIE using a suitable etching chemistry.

The spacer structures 112 may be provided to protect the underlying semiconductor material 104 during ion implantation processes (illustrated by arrows 150 in FIG. 7) associated with the formation of source/drain extension implant regions 113, halo implant regions 115, and/or deep source/drain implant regions 117 (see FIG. 4), as is well understood. The spacer structures 112 may be removed after completion of the various ion implantation steps (and/or the completion of the process steps that utilize the spacer structures 112). Ion implantation to form the source/drain extension implant regions 113, halo implant regions 115, and/or deep source/drain implant regions 117 may be realized by exposing the semiconductor substrate to a dopant ion implantation process. For example, the implant regions may be performed by exposing germanium substrate 104 to an ionizing environment with an ionic dopant species that is directed downward towards the germanium substrate 104. Suitable dopants for this process may include the various ions of boron (B), aluminum (Al), and/or indium (In) to form a pFET, and phosphorus (P), arsenic (As), and/or antimony (Sb) to form an nFET. Further, source/drain implant regions 117 may be silicided (119) using conventional silicidation techniques known in the art. Subsequent to the ion implantation steps, the integrated circuit is formed substantially as illustrated and described above with regard to FIG. 3.

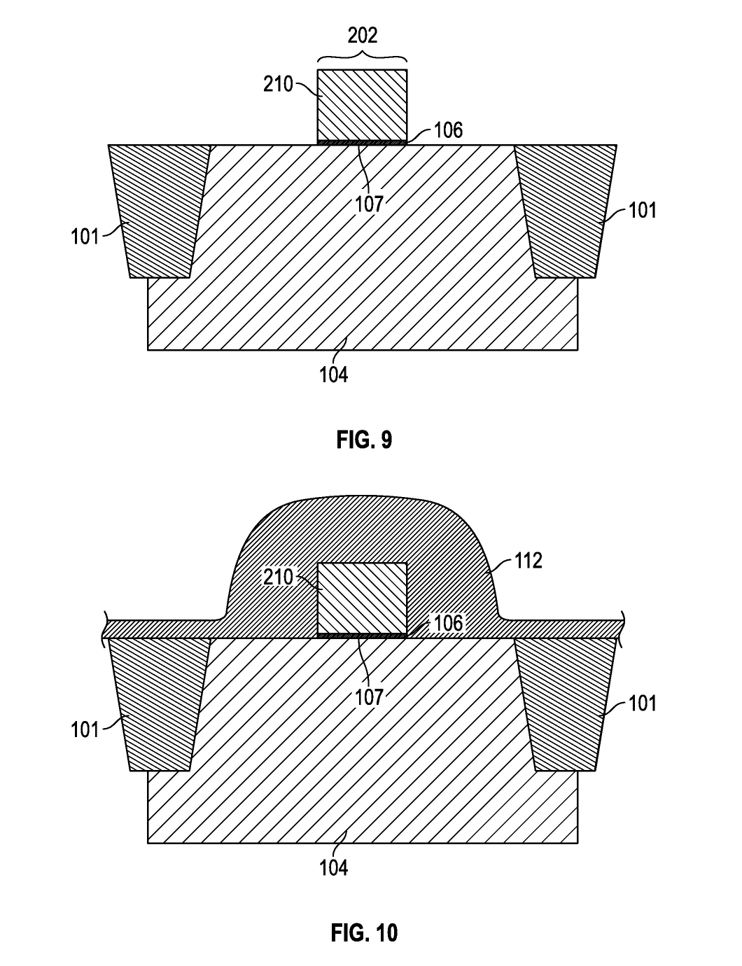

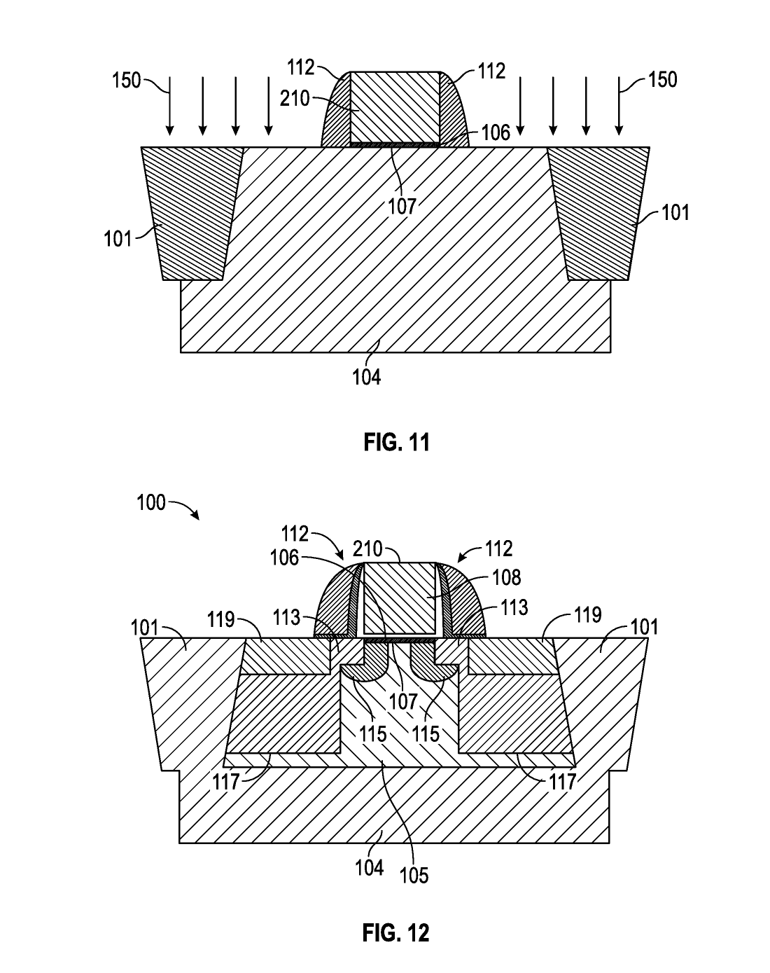

In an alternative embodiment, the metal gate stack 102 is fabricated using gate last or replacement metal gate (RMG) techniques that are well known in the art. For example, with reference to FIG. 8, the gate insulation layer 106 is provided over the IL 107 as described above with respect to FIG. 4. Thereafter, a temporary or “dummy” gate element 210 may be initially provided over the gate insulation layer 106 that includes polycrystalline silicon, although other replaceable materials could be used instead of polycrystalline silicon. Optionally, an etch stop layer of a suitable dielectric material (not shown) is first provided over the gate insulation layer 106 to protect the gate insulation layer during a subsequent etching step to remove the dummy gate element 210, as will be described in greater detail below. The dummy gate element 210 is provided by depositing a layer of polycrystalline silicon, e.g., using LPCVD by the hydrogen reduction of silane. Typically, the polycrystalline silicon layer will have a thickness within the range of about 50 nm to about 100 nm. With reference to FIG. 9, the polycrystalline silicon layer along with the gate insulation layer 106 is etched using an appropriate etch mask and etch chemistry to form dummy gate stack 202. Subsequently, with reference to FIGS. 10 and 11, the spacer structures 112, the source/drain extension implant regions 113, halo implant regions 115, and/or deep source/drain implant regions 117 may be formed using the procedures described above with regard to FIGS. 6 and 7.

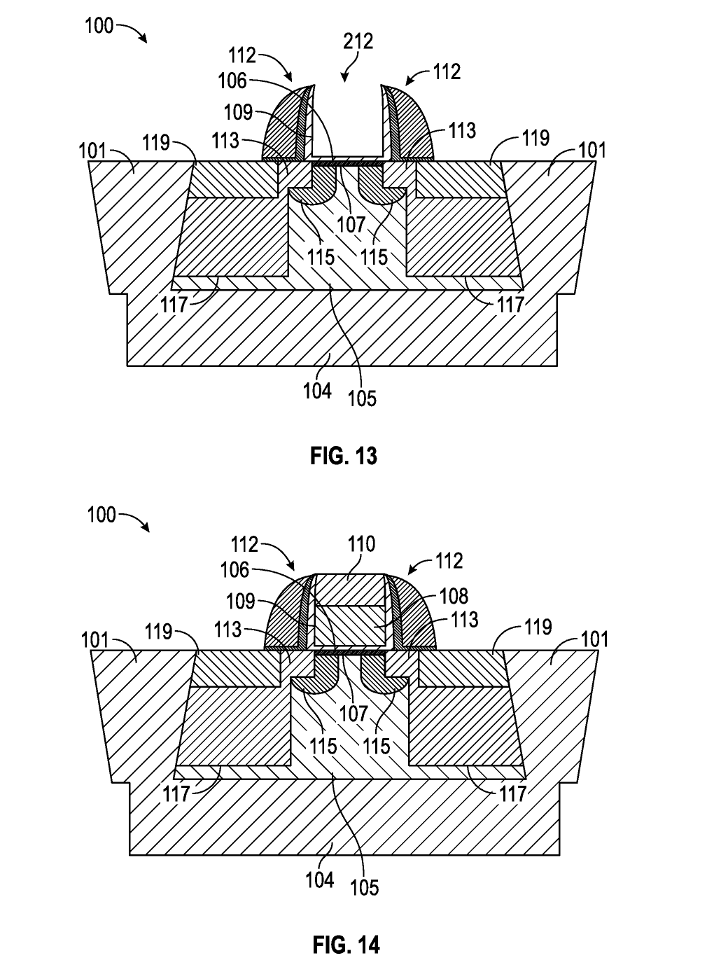

With reference now to FIGS. 12 and 13, the dummy gate element 210 is then removed using an appropriate etchant chemistry that selectively etches the material used for the temporary gate element, leaving a gate recess region 212. The etchant chemistry, the etching conditions, the duration of the etching process, and other factors may be controlled as needed to ensure that the temporary gate element 210 is removed. The replacement gate process continues by filling the gate recess region 212 with the optional work function modifying material 109, metal gate electrode element 108, and capping layer 110, as shown in FIG. 14.

Although not illustrated, with regard to any of the embodiments described above, the partially-formed integrated circuit is completed in a conventional manner by, for example, providing electrical contacts to the source and drain regions 117 and to the gate electrodes 108, depositing interlayer dielectrics, etching contact vias, filling the contact vias with conductive plugs, and the like as are well known to those of skill in the art of fabricating integrated circuits. Additional post-processing may include the formation of one or more metal layers (M1, M2, etc.) and interlayer dielectric layers therebetween to complete the various electrical connections in the integrated circuit. The present disclosure is not intended to exclude such further processing steps as are necessary to complete the fabrication of a functional integrated circuit, as are known in the art.

Thus, embodiments of the present disclosure provide methods for depositing an aluminum oxide layer over germanium substrates using ALD in the fabrication of integrated circuits. Beneficially, the described methods do not substantially contribute to the re-growth of the germanium oxide interfacial layer, do not substantially contribute to an increase in interface state density (Dᵢₜ), and do not substantially contribute to increased gate current leakage (I_{g}). Additionally, the described methods are suitable for integration into existing integrated circuit fabrication process flows, including both gate-first and gate-last process flows.

While at least one exemplary embodiment has been presented in the foregoing detailed description of the disclosure, it should be appreciated that a vast number of variations exist. It should also be appreciated that the exemplary embodiment or exemplary embodiments are only examples, and are not intended to limit the scope, applicability, or configuration of the disclosure in any way. Rather, the foregoing detailed description will provide those skilled in the art with a convenient road map for implementing an exemplary embodiment of the disclosure. It being understood that various changes may be made in the function and arrangement of elements described in an exemplary embodiment without departing from the scope of the disclosure as set forth in the appended claims.

1. A method for fabricating an integrated circuit comprising:
providing a germanium-based semiconductor substrate comprising a GeOₓ layer formed thereon;
determining a desired tuning of an atomic layer deposition (ALD) aluminum oxide layer to be deposited over the GeOₓ layer with respect to qualities of interfacial density of energy states (Dᵢₜ) and gate capacitance, wherein said determining step comprises selecting a first oxygen-containing precursor for minimizing Dᵢₜ and selecting a second oxygen-containing precursor for minimizing gate capacitance, wherein the first oxygen-containing precursor is a different chemical species from the second oxygen-containing precursor;
exposing the semiconductor substrate to first and second atomic layer deposition (ALD) processes, wherein the first ALD process comprises:
exposing the semiconductor substrate to a first gaseous precursor comprising aluminum; and
exposing the semiconductor substrate to a second gaseous precursor comprising the first oxygen-containing precursor,
wherein the second ALD process comprises:
exposing the semiconductor substrate to the first gaseous precursor comprising aluminum; and
exposing the semiconductor substrate to a third gaseous precursor comprising the second oxygen-containing precursor.

2. The method of claim 1, wherein exposing the semiconductor substrate to the first gaseous precursor comprises exposing the semiconductor substrate to a trimethylaluminum precursor.

3. The method of claim 2, wherein exposing the semiconductor substrate to the second gaseous precursor comprises exposing the semiconductor substrate to an ozone precursor.

4. The method of claim 3, wherein exposing the semiconductor substrate to the third gaseous precursor comprises exposing the semiconductor substrate to a water precursor.

5. The method of claim 4, wherein said determining step further comprises selecting an order of deposition with respect to the steps of exposing the semiconductor substrate to the first ALD process and to the second ALD process, wherein, for tuning to minimize Dᵢₜ as compared to gate capacitance, the method is characterized wherein exposing the semiconductor substrate to the first ALD process is performed prior to exposing the semiconductor substrate to the second ALD process.

6. The method of claim 4, wherein said determining step further comprises selecting an order of deposition with respect to the steps of exposing the semiconductor substrate to the first ALD process and to the second ALD process, wherein, for tuning to minimize gate capacitance as compared to Dᵢₜ, the method is characterized wherein exposing the semiconductor substrate to the first ALD process is performed after exposing the semiconductor substrate to the second ALD process.

7. The method of claim 5, wherein exposing the semiconductor substrate to the first ALD process is performed for two or three ALD cycles.

8. The method of claim 7, wherein exposing the semiconductor substrate to the second ALD process is performed subsequent to the first ALD process and for a number of cycles sufficient to deposit an ALD layer to a thickness of about 1 nm to about 8 nm.

9. The method of claim 10, wherein exposing the semiconductor substrate to the second ALD process is performed before subsequent to the first ALD process and for a number of cycles sufficient to deposit the ALD layer to a thickness of about 1 nm to about 8 nm.

10. The method of claim 6, wherein exposing the semiconductor substrate to the second ALD process is performed for two or three ALD cycles.

11. The method of claim 1, wherein exposing the semiconductor substrate to the first and second ALD processes comprises depositing an Al₂O₃ gate insulation layer, and further comprising forming a metal gate stack over the gate insulation layer in a gate-first process flow.

12. The method of claim 1, wherein exposing the semiconductor substrate to the first and second ALD processes comprises depositing an Al₂O₃ gate insulation layer, and further comprising forming a metal gate stack over the gate insulation layer in a gate-last process flow.

13. A method for fabricating an integrated circuit comprising:
providing a germanium-based semiconductor substrate comprising a GeOₓ layer formed thereon;
determining a desired tuning of an atomic layer deposition (ALD) aluminum oxide layer to be deposited over the GeOₓ layer with respect to qualities of interfacial density of energy states (Dᵢₜ) and gate capacitance, wherein said determining step comprises selecting a first level of an oxygen-containing precursor for minimizing Dᵢₜ and selecting a second level of the oxygen-containing precursor for minimizing gate capacitance, wherein the first level of the oxygen-containing precursor is greater than the second level of the oxygen-containing precursor;
exposing the semiconductor substrate to first and second atomic layer deposition (ALD) processes, wherein the first ALD process comprises:
exposing the semiconductor substrate to a first gaseous precursor comprising aluminum; and
exposing the semiconductor substrate to a second gaseous precursor comprising an oxygen-containing precursor at the first level,
wherein the second ALD process is performed subsequent to the first ALD process and comprises:
exposing the semiconductor substrate to the first gaseous precursor comprising aluminum; and
exposing the semiconductor substrate to the second gaseous precursor comprising the oxygen-containing precursor at the second level that is less than the first level.

14. The method of claim 13, wherein exposing the semiconductor substrate to the first gaseous precursor comprises exposing the semiconductor substrate to a trimethylaluminum precursor.

15. The method of claim 14, wherein exposing the semiconductor substrate to the second gaseous precursor comprises exposing the semiconductor substrate to an ozone precursor.

16. The method of claim 14, wherein exposing the semiconductor substrate to the second gaseous precursor comprises exposing the semiconductor substrate to a water precursor.

17. The method of claim 13, wherein exposing the semiconductor substrate to the second gaseous precursor at the first level comprises exposing the semiconductor substrate to the second gaseous precursor for a time period of about 2 seconds to about 20 seconds.

18. The method of claim 17, wherein exposing the semiconductor substrate to the second gaseous precursor at the second level comprises exposing the semiconductor substrate to the second gaseous precursor for a time period of about 0.5 seconds to about 18 seconds.

19. The method of claim 13, wherein exposing the semiconductor substrate to first and second atomic layer deposition (ALD) processes comprises depositing an Al₂O₃ gate insulation layer, and wherein the method further comprises forming a metal gate stack over the gate insulation layer in a gate-first or a gate-last process flow.

20. (canceled)

21. The method of claim 13, further comprising exposing the semiconductor substrate to a third ALD process, wherein the third ALD process is performed subsequent to the second ALD process and comprises exposing the semiconductor substrate to the first gaseous precursor comprising aluminum and exposing the semiconductor substrate to the second gaseous precursor comprising the oxygen-containing precursor at a third level that is less than the second level, wherein the second level comprises a reduction in oxygen-containing precursor of about 5% or greater as compared to the first level, and wherein the third level comprises a reduction in oxygen-containing precursor of about 5% or greater as compared to the second level.
